(19) United States
(12) Patent Application Publication
(10) Pub. No.: US 2026/0122821 A1
(43) Pub. Date: Apr. 30, 2026

(54) CONNECTION KIT FOR ELECTRIC APPARATUSES, IN PARTICULAR OF THE KIND TO BE FIXED TO A WALL

(71) Applicant: CAREL INDUSTRIES S.P.A., Brugine PD (IT)

(72) Inventors: Riccardo TETTAMANTI, Brugine PD (IT); Filippo MANDARA, Brugine PD (IT); Paolo MARAFIN, Brugine PD (IT)

(21) Appl. No.: 19/479,847

(22) PCT Filed: Mar. 11, 2025
(86) PCT No.: PCT/IB2025/052589

§ 371 Date: Oct. 29, 2025

(30) Foreign Application Priority Data
Mar. 11, 2024 (IT) 102024000005371

(51) Int. Cl. H05K 7/14

(52) U.S. Cl. CPC H05K 7/1484; H05K 7/1478

(57) ABSTRACT

A kit includes an electric appliance, which for example may be an electrical control appliance of the type to be installed on a wall, and a coupling element to be inserted at the rear in a unique way to couple the electric appliance to another electric appliance, wherein the coupling element has a rigid body defining protrusions or grooves that can engage respective grooves or protrusions of the external casing of the appliance and also has a bus of electrical lines that terminate at their ends with exposed electrical connectors, in such a way as to be able to come into contact with exposed electrical pads of the electric appliance or electric appliances to be contacted to form a single body that can be understood as a single appliance.

### TECHNICAL FIELD

This invention relates generally to electric appliances and more particularly to a kit for connecting an electric appliance to another electric appliance using a coupling element between the two appliances to form a single one.

### BACKGROUND

The electrical control appliances are devices, for example like the one illustrated in FIG. 1, which have inside a microcontroller that manages the entire appliance. Typically, such known electrical control appliances may comprise at least one microcontroller-controlled switch, which may be for example a common relay interfaced to the outside through connectors, as well as a sensor also connected to the microcontroller. The sensor provides the microcontroller with measured values and the microcontroller, as a function of these measured values, controls the switch (or switches) of the electrical control appliance. Typically, these electrical control appliances can be installed on a wall or on a DIN guide, so they have a flat resting surface for resting against the wall or the guide.

A drawback that occurs when installing appliances of this type consists in the fact that they could in theory be connected to other electrical control appliances so that they can share information on measurements detected by the sensors of the various appliances, but at the moment to do this it is necessary to engage connectors of the switches of each appliance so that the appliances can communicate with each other. When several electrical control appliances are interconnected with each other to compose a control panel, there are fewer free connectors available for external devices that must be controlled by each electrical control appliance and there are also external cables that run from one device to another, which are unpleasant to the eye and visually give the impression that the control panel is not monolithic.

### SUMMARY

These drawbacks are at least partially overcome with a kit as defined in the appended claims. The kit according to this invention comprises an electric appliance, which for example may be an electrical control appliance of the type to be installed on a wall or on a DIN guide, and a coupling or connecting element for coupling the electric appliance to another electric appliance, wherein the coupling or connecting element has a rigid body defining protrusions or grooves that can engage respective grooves or protrusions (of the external casing) accessible from the outside rear of the appliance and also has a bus of electrical lines that terminate at their ends with exposed electrical connectors, so as to be able to come into contact with exposed electrical pads of the electric appliance or electric appliances to be contacted.

Said “electric appliance” is therefore to be understood as a first electric appliance, such as an electrical control appliance of the type to be installed on a wall or on a guide, for example of the DIN type, and said “another electric appliance” is a second electric appliance, such as an electric appliance of the type to be installed on a wall or on a guide, for example a DIN guide.

Within the scope of the present invention, hereinafter, the expression “first appliance” means a first electric appliance, such as an electrical control appliance of the type to be installed on a wall or on a guide, for example of the DIN type, and similarly the expression “second appliance” means a second electric appliance, such as of the type to be installed on a wall or on a guide, for example a DIN guide, designed to be electrically connected with the first appliance to exchange digital data signals with said first appliance and/or to be electrically powered by the first appliance.

More in detail, the at least one first appliance of the kit according to the present invention includes a support on which first electrical lines and first electrical pads are defined. Each electrical line of the first electrical lines is connected to a respective electrical pad of the first electrical pads. Furthermore, the first electrical lines comprise data lines intended to convey digital data signals. The first support, the first electrical lines and the first electrical pads may be part of a first printed circuit or define a first printed circuit of the first appliance.

The at least one first appliance of the kit further includes a microcontroller, that is to say, a first microcontroller, installed on the support, that is to say, associated with the support, and having connectors connected to the data lines.

The at least one first appliance of the kit further includes an external casing. The external casing of the first appliance encloses the support, leaving the first electrical pads exposed. In other words, the external casing comprises an opening that leaves the first electrical pads uncovered.

The external casing of the first appliance also defines first grooves and/or protrusions. In other words, the external casing of the first appliance is provided with first grooves and/or protrusions.

As mentioned above, the kit according to the present invention further comprises a coupling or connecting element for either coupling or connecting the first appliance to a second appliance. The coupling or connecting element is designed, that is, to connect the first appliance to a second appliance.

According to the present invention, the coupling or connecting element has, in turn, a rigid body defining on a first side second protrusions and/or grooves complementary to the first grooves and/or protrusions. In other words, the first grooves and/or protrusions of the external casing of the first appliance and the second protrusions and/or grooves of the coupling or connecting element are configured to achieve a mutual shape coupling, or other type of coupling. Furthermore, the coupling or connecting element comprises a bus of electrical lines terminating, at a first end, with first electrical connectors exposed from the first side—that is, the side at which the rigid body is provided with second protrusions and/or grooves and, at a second end opposite to the first end, with second electrical connectors exposed from a second side opposite to the first side. In other words, the coupling or connecting element is provided with a bus of electrical lines having first and second electrical connectors. The first electrical connectors and the second electrical connectors are made at a first end and a second end, respectively, opposite each other, of the same electrical lines. The first electrical connectors are exposed or face the first side, for a connection with first electrical pads of the first appliance. The second electrical connectors are exposed or face the second side, opposite the first side, for connection with second electrical pads of a second appliance.

In practice, according to the present invention, the first appliance and the coupling or connecting element are such that, when the coupling or connecting element is mounted with the second protrusions and/or grooves engaging the first grooves and/or protrusions of the first appliance, the exposed first electrical connectors of the bus of electrical lines come into contact with the first electrical pads establishing an electrical continuity between the electrical lines of the bus and the first electrical lines of the first appliance.

In other words, the first appliance and the coupling or connecting element are configured such that, when the second protrusions and/or grooves of the coupling or connecting element engage the first grooves and/or protrusions of the first appliance, the exposed first electrical connectors of the bus of electrical lines of the coupling or connecting element come into contact with the first electrical pads of the support of the first appliance. In other words, in use, following the mutual coupling between the first grooves and/or protrusions and the second protrusions and/or grooves, the first electrical connectors of the bus of electrical lines come into contact with the first electrical pads, thus electrically connecting the electrical lines of the bus and the first electrical lines of the first appliance.

In this way, advantageously, the first appliance can be mechanically and electronically connected to the coupling or connecting element. In fact, through the mutual coupling of the first protrusions and/or grooves, the first appliance and the coupling or connecting element are mutually associated and the first electrical connectors are electronically connected to the first pads. Furthermore, through the coupling or connecting element, in particular through the exposed second electrical connectors of the bus of electrical lines, the first appliance can also be electronically connected to a second appliance.

According to a preferred aspect of the present invention, the rigid body is shaped so as to have a centerline plane, wherein said first side and said second side are opposite with respect to the centerline plane.

According to a further preferred aspect of the present invention, the bus of electrical lines is anchored to the rigid body with the first exposed electrical connectors facing from the first side and with the second exposed electrical connectors facing from the second side. The term “anchored” means that the bus of electrical lines is permanently associated with the rigid body. Therefore, in the absence of deliberate separation efforts, that is, disassociation or violation, exercised by an operator, the bus of electrical lines remains fixed or associated with the rigid body.

According to a further preferred aspect of the present invention, the bus of electrical lines is removably anchored to the rigid body, that is to say, in a removable manner. Advantageously, in case of failure of one of the electrical lines of the bus of electrical lines it is possible to replace only the bus of electrical lines and not the entire coupling or connecting element. Conversely, in case of breakage of the rigid body, it is possible to replace only the free body and not also the bus of electrical lines.

According to a further preferred aspect of the present invention, the bus of electrical lines is embedded in the rigid body. In other words, the rigid body houses the bus of electrical lines leaving the first electrical connectors and the second electrical connectors exposed or uncovered. In yet other words, the rigid body defines a seat in which the bus of electrical lines is received or housed leaving the first electrical connectors and the second electrical connectors uncovered.

According to a further preferred aspect of the present invention, the first electrical lines comprise first electrical lines of the first appliance connected to connectors of an electricity supply source. In other words, the first electrical lines comprise first electrical lines of the first appliance designed to be connected to connectors of an electricity supply source. In this way, advantageously, in use, if a second appliance is not connected to a respective electricity supply source, it is also possible to power this second appliance, by electrically connecting it, through the coupling or connecting element, to the first electric appliance.

According to a further preferred aspect of the present invention, the external casing of the first appliance defines a first flat resting surface for resting against a wall or DIN guide. In other words, the external casing of the first appliance comprises a substantially flat resting first surface, intended in use to be fixed or resting on a wall or a DIN guide. The first flat surface faces a rear side of the first appliance, opposite to a side of use of the first appliance. The side of use refers to the side that is facing, in use, the user.

According to a preferred aspect of the present invention, the first flat support surface leaves exposed the first electrical pads. In other words, the first flat surface comprises an opening facing the first electrical pads. In this way, the first pads are accessible from the rear side of the first appliance, to be engaged by the first electrical connectors of the coupling or connecting element.

According to a further preferred aspect of the present invention, the first grooves and/or protrusions and the second protrusions and/or grooves are configured to be inserted into each other or mutually engage in an insertion direction. The insertion direction goes from the rear side to the use side of the first appliance. It follows that the rigid body and the external casing of the first appliance are configured such that, in order to mutually couple the first grooves and/or protrusions to the second protrusions and/or grooves, the second protrusions and/or grooves are inserted on or in the first grooves and/or protrusions along an insertion direction that goes from the rear side, or from the part of the flat support surface, to the side of use of the first appliance. The fact that the coupling or connecting element is inserted from the rear side, that is, from the part of the flat support surface, causes the coupling or connecting element to be hidden from view when the first appliance is installed on a wall or on a DIN guide. For this reason, when the first appliance is installed on the DIN guide or on the wall, the first appliance and the coupling or connecting element appear from the side of use substantially as a unitary body or single entity or mono block. For this reason, when the first appliance is installed on the DIN guide or on the wall, it is not possible to extract or remove the coupling or connection element from it, in order to guarantee greater safety. Therefore, in use, tampering with the assembly formed by the first appliance and the coupling or connection element is made particularly difficult.

According to a further preferred aspect of the present invention, moreover, the rigid body defines a flat bottom surface such that, when the rigid body of the coupling or connecting element engages the first grooves and/or protrusions and the first exposed electrical connectors come into contact with the first electrical pads, the flat bottom surface of the rigid body is coplanar with the first flat support surface of the first appliance. In this way, it is therefore made even more difficult to be able to extract or remove the coupling or connecting element. In fact, advantageously, the coupling or connecting element cannot be accidentally removed, since, in use, its flat bottom surface is abutted against the wall (or the DIN guide).

Furthermore, according to a further preferred aspect of the present invention, the external casing of the first appliance defines the first grooves and/or protrusions, which extends on a first side surface of the first appliance. The external casing of the first appliance is provided with the first grooves and/or protrusions. The first grooves and/or protrusions are in particular made at a first side surface of the first appliance; in particular the first grooves and/or protrusions are defined on a first {side surface of the external casing of the first appliance. Preferably, the first side surface of the external casing is a surface substantially orthogonal to the flat support surface. Preferably, the first side surface is a surface lying on or facing a side of the appliance. The side is a side of the first appliance that extends between a rear side and a side of use, opposite the rear side.

According to a preferred aspect of the present invention, on the second side, opposite the first side, the rigid body has third protrusions and/or grooves. The rigid body at the second side has third protrusions and/or grooves. Preferably, the third protrusions and/or grooves are configured to be associated with corresponding fourth grooves and/or protrusions made on the second appliance. In this way, a second appliance can be mechanically connected to the first appliance through the coupling or connecting element.

According to a preferred aspect of the present invention, the rigid body has a main portion. The main portion comprises, in turn, a base from the opposite ends of which two side portions protrude. The side portions are preferably arranged transversely, more preferably, orthogonally to the base. Preferably the main portion is substantially U-shaped. More preferably, the rigid body has a main portion having a substantially U-shaped section along the centerline plane. Preferably, the base defines the flat bottom surface.

According to a preferred aspect, the second protrusions and/or grooves are defined, that is to say are made, on a first side at side portions.

According to a preferred aspect, the third grooves and/or protrusions are defined, that is to say are made, on a second side at side portions.

According to a preferred aspect of the present invention, the rigid body has a first auxiliary portion and a second auxiliary portion. The first auxiliary portion is associated with the base at the first side and the second auxiliary portion is associated with the central portion at the second side. Preferably, the first auxiliary portion and the second auxiliary portion are arranged transversely, more preferably orthogonally, to the base. More preferably, the first auxiliary portion and the second auxiliary portion extend substantially parallel to the side portions of the main portion of the rigid body. Preferably, the bus of electrical lines is at least partially housed in the first auxiliary portion and in the second auxiliary portion. Preferably each auxiliary portion is provided with a respective opening. such that through the opening of the first auxiliary portion the first electrical connectors of the bus of electrical lines are accessible from the first side and that through the opening of the second auxiliary portion the second electrical connectors of the bus of electrical lines are accessible from the second side. In other words, the first electrical connectors are exposed on the first side or accessible from the first side through the opening of the first auxiliary portion and the second connectors are exposed on the first side or accessible from the second side through the opening of the second auxiliary portion.

As mentioned above, through the coupling or connecting element, in particular through the exposed second electrical connectors of the bus of electrical lines, the first appliance can also be electronically connected to a second appliance. Thus, the coupling or connecting element is an electromechanical connector, that is, configured to mechanically and electrically connect a first appliance and a second appliance.

Even more preferably, the third protrusions and/or grooves are arranged symmetrically or asymmetrically with respect to the second protrusions and/or grooves. In particular, the second protrusions and/or grooves and the third protrusions and/or grooves are arranged symmetrically or asymmetrically with respect to each other with respect to the centerline plane of the rigid body. If the second protrusions and/or grooves and the third protrusions and/or grooves of the rigid body are arranged asymmetrically with respect to each other with respect to the centerline plane, this advantageously determines the fact that the coupling or connecting element can be coupled respectively to the first grooves and/or protrusions and to the fourth grooves and/or protrusions only in a single predefined spatial orientation.

According to a preferred aspect of the present invention, the first appliance and the coupling or connecting element are configured to be mutually coupled in a reversible manner. That is to say that the first appliance and the coupling or connecting element are configured to be coupled to each other in a removable manner. It follows that the first appliance and the coupling or connecting element can be repeatedly coupled or separated from each other as needed. According to a further preferred aspect of the present invention, the first appliance and the coupling or connecting element are configured to be coupled to each other stably and in a reversible manner. Therefore, in the absence of deliberate separation efforts exerted by an operator, the rigid body remains fixed or associated with the first appliance.

According to a further preferred aspect, the coupling or connecting element is configured to be coupled in a reversible manner to the first appliance and to the second appliance, if it is part of the kit. The coupling or connecting element is thus configured to reversibly connect the first appliance to the second appliance. The coupling or connecting element is connectable and disconnectable as required with respect to the first appliance and the second appliance, allowing through a kit comprising at least a first appliance, a second appliance and a coupling or connecting element to obtain a modular electrical panel.

The second appliance can also be connected to a third electric appliance with a same coupling or connecting element to repeat the modular configuration described herein.

Preferably, the second protrusions and/or grooves and the first grooves and/or protrusions are configured to slide in a reversible manner within each other so that said first appliance and said coupling or connecting element are mutually coupled/decoupled in a reversible manner.

Alternatively, according to the last preferred aspect, the first appliance and the coupling or connecting element are configured to be coupled to each other in an irreversible manner. That is to say that once the first appliance is coupled to the coupling or connecting element, the separation between the first appliance and the coupling or connecting element causes the breakage or permanent deformation of one of either the first appliance, in particular of its external casing, or of the coupling or connecting element. The separation of the first appliance and the coupling or connecting element does not, therefore, allow them to be re-coupled.

Preferably, the second protrusions and/or grooves and the first grooves and/or protrusions are configured to irreversibly snap into each other so that said first appliance and the coupling or connecting element are irreversibly coupled to each other.

According to a preferred aspect of the present invention, the kit comprises a second appliance.

Preferably, moreover, the second appliance is the same or similar to the first appliance for forming the above-mentioned modular configuration.

Preferably, the second appliance includes, in turn, a second support on which second electrical lines and second electrical pads are defined. Each electrical line of the second electrical lines is connected to a respective electrical pad of the second electrical pads. The second electrical lines comprise second data lines intended to convey digital data signals. The second electrical lines may further comprise second supply lines. The second support, the second electrical lines and the second electrical pads may be part of a second printed circuit or define a second printed circuit of the second appliance

Preferably, the second appliance further includes a second microcontroller installed on the second support and having second connectors connected to the second data lines.

Preferably, the second appliance further includes at least one second switch installed on the second support and connected to the second microcontroller so as to be controlled by the second microcontroller.

Preferably, the second appliance further includes at least one second sensor installed on the second support and connected to said second microcontroller so as to provide the second microcontroller with signals relating to measured quantities.

Preferably, the second appliance further includes a second external casing enclosing the second support leaving the respective second electrical pads exposed or uncovered. In other words, the external casing of the second appliance comprises an opening that leaves the second electrical pads uncovered.

Preferably, the external casing of the second appliance defines or is provided with fourth grooves and/or protrusions complementary to the third protrusions and/or grooves. Similar to what was said above with reference to the first grooves and/or protrusions and the second protrusions and/or grooves, the fourth grooves and/or protrusions and the third protrusions and/or grooves are also configured to form a mutual coupling, such as for example a shape coupling. The first appliance can then be mechanically connected to the second appliance by mutually coupling the third protrusions and/or grooves with the fourth grooves and/or protrusions.

Preferably, the second appliance and the coupling or connecting element are configured such that when the coupling or connecting element is assembled with the third protrusions and/or grooves engaging the fourth grooves and/or protrusions of the second appliance the exposed second electrical connectors of the bus of electrical lines of the coupling or connecting element come into contact with the second electrical pads of the second appliance.

The first appliance can then exchange data signals with either the second appliance or electrically power the second appliance thanks to the bus lines of the coupling or connecting element that are connected to the first electrical pads and the second electrical pads, respectively through the first electrical connectors and the second electrical connectors. The first appliance can therefore be mechanically and electrically connected to the second appliance through the coupling or connecting element. As mentioned, the coupling or connecting element is, therefore, an electromechanical connector.

According to a preferred aspect of the present invention, the external casing of the second appliance defines the fourth grooves and/or protrusions. Preferably, the fourth grooves and/or protrusions extend on a second side surface of the second appliance, that is, on a second side surface of the external casing of the second appliance. Preferably, in use, the second side surface of the external casing of the first appliance and the second side surface of the external casing of the second appliance face each other. In other words, the first appliance and the second appliance are intended to be arranged side by side, that is, with the first side surface and the second side surface facing each other.

According to a further preferred aspect of the present invention, the fourth grooves and/or protrusions and the third protrusions and/or grooves are configured to be inserted into each other or mutually engage in the above-mentioned insertion direction. The insertion direction goes from the rear side of the first appliance and the second appliance to the side of use of the first appliance and the second appliance. Similarly to the first appliance, for the second appliance the rear side is also opposite to the side of use, and is intended to be facing the wall or DIN guide. It follows that the rigid body and the external casing of the first appliance and of the second appliance are configured in such a way that:
to mutually couple the first grooves and/or protrusions to the second protrusions and/or grooves, the second protrusions and/or grooves are inserted on or in the first grooves and/or protrusions along the insertion direction;
to mutually couple the third protrusions and/or grooves to the fourth grooves and/or protrusions, the third protrusions and/or grooves are inserted on or in the fourth grooves and/or protrusions along the above-mentioned insertion direction.

The fact that the coupling or connecting element is inserted from the rear side of the first appliance, and thus from the rear side of the second appliance, causes the coupling or connecting element to be hidden from view when the first appliance and the second appliance are installed on a wall or on a DIN guide. For this reason, when the first appliance and the second appliance are installed on the DIN guide or the wall, the first appliance, the second appliance, and the coupling or connecting element appear from the side of use substantially as a unitary or mono-block body or single entity. Therefore, in use, tampering with the assembly formed by the first appliance and the coupling or connection element is made particularly difficult.

According to a preferred aspect of the present invention, the external casing of the second appliance defines a second flat resting surface against the wall or a DIN guide. In other words, the external casing of the second appliance comprises a substantially flat second surface, intended in use to be fixed or resting on a wall or a DIN guide. The second flat surface faces a rear side of the second appliance, opposite to a side of use of the second appliance.

According to a preferred aspect of the present invention, the second flat support surface leaves exposed the second electrical pads. In other words, the second flat surface comprises at least one opening facing the second electrical pads. In this way, the second pads are then accessible from a rear side of the second appliance to be engaged by the second electrical connectors of the coupling or connecting element. The rear side of the second appliance, as for the first appliance, is a side opposite to the side of use thereof.

According to a preferred aspect of the present invention, the external casing of the second appliance is configured so that, when the rigid body of the coupling or connecting element engages the first grooves and/or protrusions and the fourth grooves and/or protrusions, and when the exposed first and second electrical connectors come into contact with the first electrical pads and second electrical pads, respectively, the flat bottom surface of the rigid body is coplanar with the first flat support surface and the second flat support surface. Therefore, as mentioned above, advantageously, the coupling or connecting element cannot be accidentally removed, since, in use, its flat bottom surface is abutted against the wall (or the DIN guide). For this reason, when the first appliance is installed on the DIN guide or on the wall, it is not possible to extract or remove the coupling or connection element from it, in order to guarantee greater safety.

According to a preferred aspect of the present invention, the second electrical lines comprise second supply lines of the second appliance connected to supply pads of the second electrical pads. Through the coupling or connecting element it is possible to connect the supply pads of the first electrical pads with the supply pads of the second electrical pads. Preferably, the second appliance is provided with a supply management block or unit connected to the second supply pads and/or to the second supply lines. The supply management unit is connected to the second supply pads to receive a supply voltage through the coupling or connecting element. The management unit is preferably electrically connected to the microcontroller of the second appliance to manage the electricity supply.

Alternatively according to a different preferred aspect, the second electrical lines comprise second supply lines of the second appliance connected to connectors of an electricity supply source or designed to be connected to connectors of an electricity supply source.

The invention, that is, the kit, is more precisely defined in the appended claims and in the following description.

### BRIEF DESCRIPTION OF THE DRAWINGS

FIG. 1 shows an electrical control appliance of the type which can be installed on a wall.

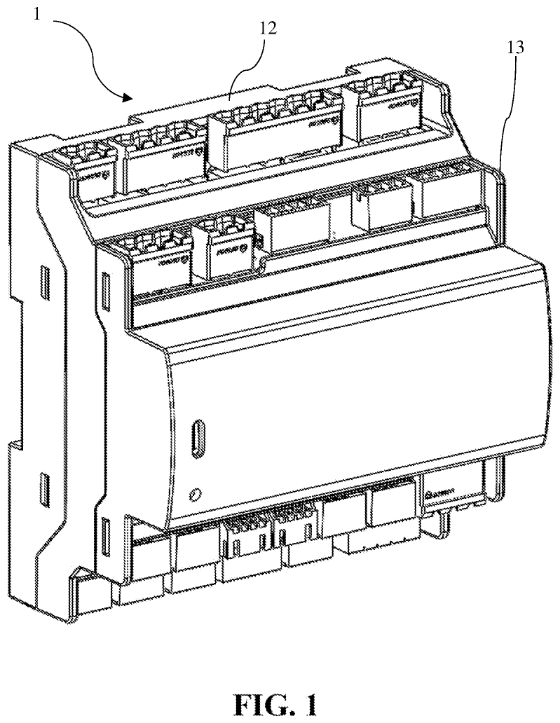

FIG. 2 shows an electric appliance and a rigid body of a coupling or connecting element of a kit according to this invention.

FIG. 3 shows: A) a perspective view of a coupling or connecting element according to this invention; B) a top view of the coupling or connecting element; C) a sectional view along the plane C-C of the coupling or connecting element; D) an exploded view of the coupling or connecting element according to this invention, showing the rigid body and the bus of lines anchored to the rigid body in a removable fashion.

FIG. 4 shows kits according to the present invention for connecting several electric appliances mechanically and electrically to each other by means of several coupling or connecting elements.

FIG. 5 illustrates how the appliances of FIG. 4 appear when mounted side by side with the coupling or connecting elements.

FIG. 6 is a perspective view of the appliances of FIG. 4, which make up an apparently monolithic electrical panel.

FIG. 7 illustrates a coupling or connecting element with a bus of lines embedded in the rigid body, according to an embodiment of the present invention.

FIG. 8 is a basic diagram of how two appliances can be connected side by side by a single coupling or connecting element according to this invention so that each appliance is supplied autonomously from the mains and the two appliances can exchange information through the bus of lines of the coupling or connecting element.

FIG. 9 is a basic diagram of how two appliances can be connected side by side by a single coupling or connecting element according to this invention so that only one appliance is autonomously supplied by the mains and the other appliance can be supplied and exchange information through the bus of lines of the coupling or connecting element.

FIG. 10 is a basic diagram of how three appliances can be connected side by side by two coupling or connecting elements according to this invention so that only one appliance is autonomously supplied by the mains and the other appliances can be supplied and exchange information through the bus of lines of the two coupling or connecting elements.

FIG. 11 is a basic diagram of how two appliances can be remotely connected by two coupling or connecting elements according to this invention so that each appliance is autonomously supplied by the mains and the two appliances can exchange information through the bus of lines of the coupling or connecting element.

FIG. 12 is a basic diagram of how two appliances can be remotely connected by a coupling or connecting element according to this invention so that each appliance is autonomously supplied by the mains and the two appliances can exchange information through the bus of lines of the coupling or connecting element connected to a connector of one of the two appliances.

FIG. 13 is a sectional view of a coupling or connecting element coupled to a first appliance in an irreversible manner.

### DESCRIPTION OF EMBODIMENTS

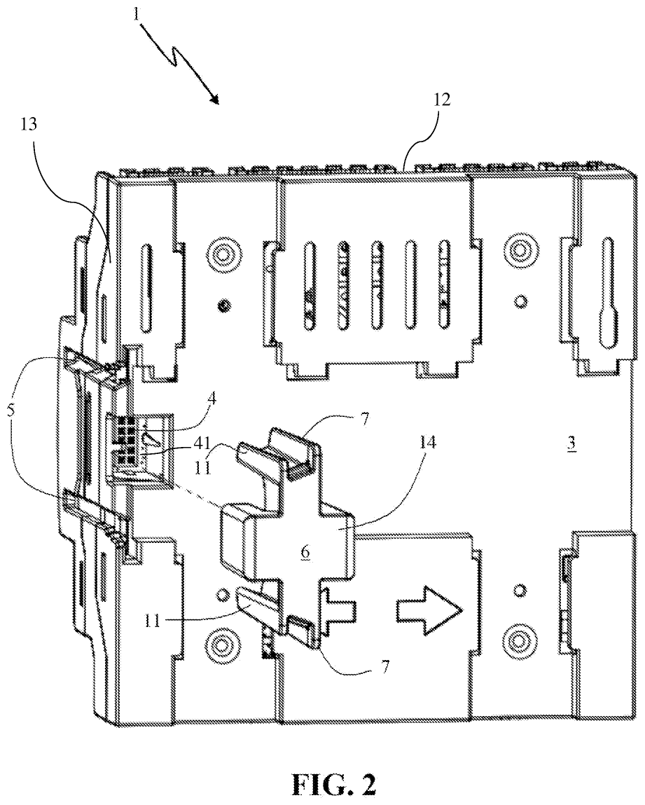

A kit according to the present invention is illustrated as an example in FIG. 2, which shows an electrical control appliance 1 of the type which can be installed on a wall and a coupling or connecting element 2 from the rear side with respect to the side of use of the control appliance. The kit according to the present invention also comprises an electrical control appliance 1 which can be installed on a DIN guide. FIG. 2 shows the electrical control appliance 1 from the side of the flat resting surface 3 for resting against a wall, that is, from a rear side of the electric appliance 1. It may be noted that the external casing 12 of the electric appliance 1 defines a flat support surface 3 that leaves the electrical pads 4 exposed and defines grooves and/or protrusions 5, or, rather, first grooves and/or protrusions, that extend on a side surface 13. In other words, the external casing 12 comprises a flat support surface 3 and a first side surface 13. Preferably, the flat support surface 3 and the first side surface 13 are arranged transversely to each other. The first side surface 13 is provided with first grooves and/or protrusions 5. In turn, the coupling or connecting element 2 has a rigid body 14 defining a flat bottom surface 6 such that, when the rigid body 14 of the coupling or connecting element 2 engages the first grooves and/or protrusions 5 of the electric appliance 1 with its protrusions and/or grooves 7, that is, with second protrusions and/or grooves 7, the flat bottom surface 6 of the rigid body 14 is coplanar with the flat support surface 3 of the appliance 1.

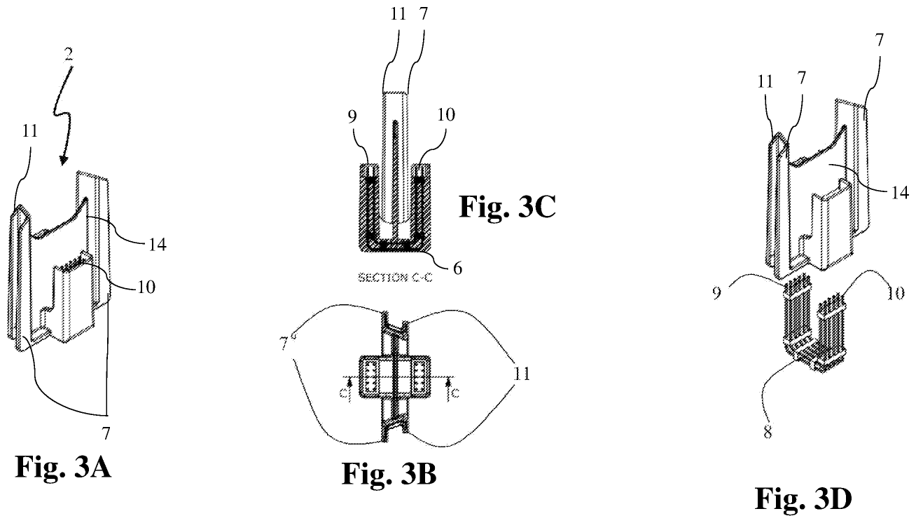

As illustrated in the various views of FIG. 3, the coupling or connecting element 2 of the kit is designed to mechanically and electrically connect a first electric appliance 1 to a second appliance, because it has a rigid body 14 defining on a first side second protrusions and/or grooves 7 complementary to the first grooves and/or protrusions 5 of the appliance to be connected, that is, of the first appliance 1, and has a bus 8 of terminating electrical lines, at a first end, with first electrical connectors 9 and, at a second end opposite the first end, with second electrical connectors 10 exposed on a second side opposite the first side. When the coupling or connecting element 2 is mounted with second protrusions and/or grooves 7 engaging the first complementary grooves and/or protrusions 5 of the appliance 1, the first exposed electrical connectors 9 of the bus 8 of electrical lines come into contact with the electrical pads 4 of the appliance 1, that is, of the first appliance 1, establishing an electrical continuity between the electrical lines of the bus 8 and the internal electrical lines of the appliance 1. In doing so, the coupling or connecting element 2 is connected both electrically and mechanically to the electric appliance 1. By connecting another electric appliance, that is, a second electric appliance 1a, on the other side of the coupling or connecting element 2, an electrical panel composed of two electric appliances electrically and mechanically connected to each other will be obtained. The coupling or connecting element 2 is configured to mechanically and electrically connect two electric appliances. In other words, the coupling or connecting element 2 is an electromechanical connector.

According to a preferred aspect shown in FIG. 3, the bus 8 of electrical lines is anchored to the rigid body 14 in a removable manner, for example by interlocking. Further, the rigid body has a centerline plane so that the first 9 and second 10 electrical connectors protrude from opposite sides with respect to the centerline plane.

According to a preferred aspect illustrated in FIG. 3, the protrusions and/or grooves 7, 11, of the rigid body 14 are not arranged symmetrically with respect to the centerline plane, so as to uniquely define a direction in which to connect two electric appliances side by side. According to this preferred aspect, the rigid body 14 is provided with second protrusions and/or grooves 7 and with third protrusions and/or grooves 11. The third protrusions and/or grooves 11 are preferably configured to be associated with corresponding fourth grooves and/or protrusions 16 of a second appliance 1a.

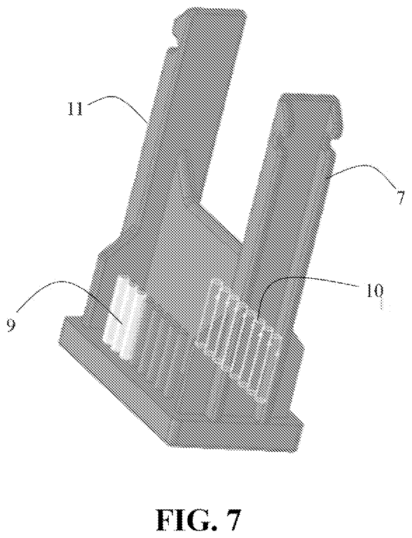

According to a preferred aspect alternative to the above-mentioned preferred aspect and illustrated in FIG. 7, the protrusions and/or grooves 7, 11, that is, the second protrusions and/or grooves 7 and the third protrusions and/or grooves 11, are symmetrically arranged on both sides of the centerline plane of the rigid body 14.

According to an aspect illustrated in FIG. 7, the bus 8 of electrical lines is embedded in the rigid body 14 so that only the first 9 and second 10 electrical connectors protrude therefrom, while the bus of electrical lines, that is, the bus 8 of electrical lines, travel, that is, are contained or housed, within the rigid body 14.

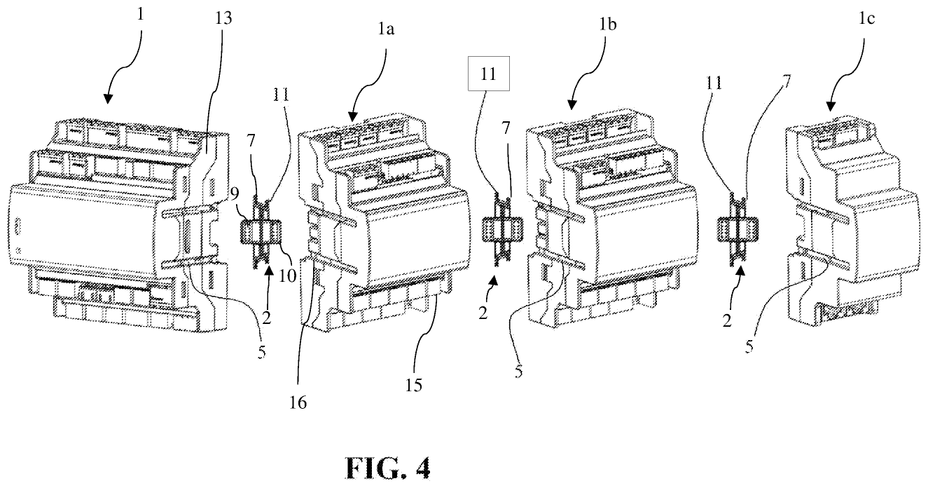

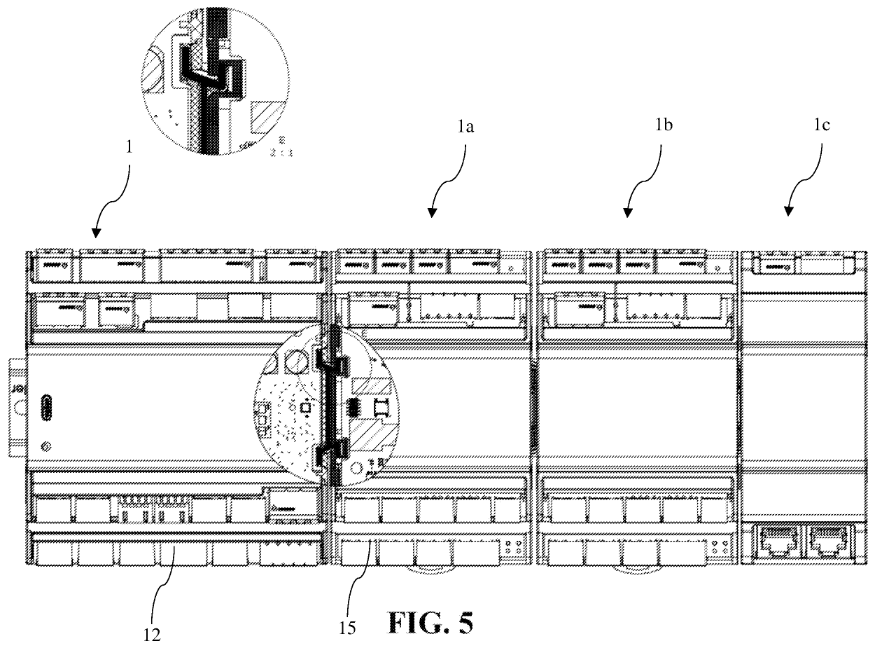

Thanks to the kit according to the present invention, it is possible to create electrical panels composed of several electric appliances, such as control appliances, mounted next to each other, that is, side by side, and mutually connected both mechanically and electrically, allowing the appliances to exchange information with each other and possibly also share the supply, giving the electrical panel a monolithic appearance, as if it were a single specially designed appliance. For example, as illustrated in FIGS. 4, 5 and 6, a composite electrical panel may be made with a kit according to the present invention comprising four electric appliances and three coupling or connecting elements. FIG. 5 shows a transparent detailed view illustrating how the asymmetrical protrusions and/or grooves of the rigid body 14 engage on both sides respective complementary grooves and/or protrusions of two electrical control appliances to be electrically and mechanically connected side by side. In other words, FIG. 5 shows a transparent detailed view illustrating how the second protrusions and/or grooves 7 and the third protrusions and/or grooves 11, asymmetrical, of the rigid body 14 engage respectively the first grooves and/or protrusions of the first electric appliance 1 and the fourth grooves and/or protrusions 16 of the second electric appliance 1a. In this way, the two electric appliances 1, 1a are mechanically connected to each other. Furthermore, in the electrical panel as illustrated in FIG. 5, the first electrical connectors 9 and the second electrical connectors 10 are connected respectively to the first electrical pads 4 of the first appliance 1 and to the second electrical pads of the second appliance 1a. In this way, the two electric appliances are also electrically connected to each other.

In particular, FIG. 4 shows an exploded view of a kit comprising four electric appliances, that is, the first electric appliance 1, a second electric appliance 1a, a third electric appliance 1b and a fourth electric appliance 1c which can be mechanically and electrically coupled by means of three coupling or connecting elements as described above.

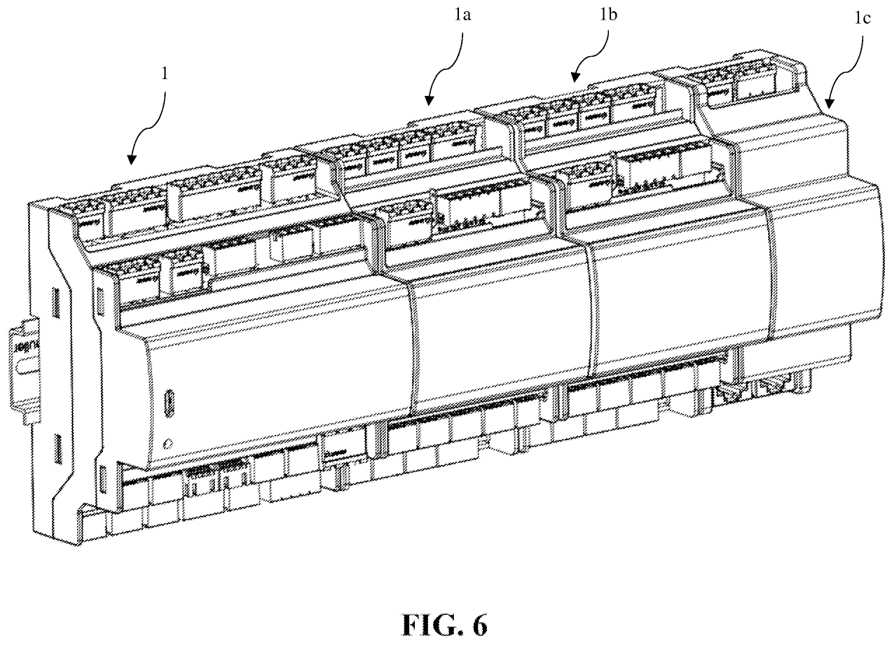

FIG. 6 shows the resulting electrical panel, which appears to be made in a single block and is composed of the four appliances of FIG. 4 connected so as to be able to exchange information with each other.

The fact that the coupling or connecting elements 2 are inserted from the part of the flat resting surfaces 3 for resting on the wall of the appliances, that is, from the rear side of the electric appliances, means that they are hidden from view when the electric appliances are installed on a wall (or on a DIN guide) and that the coupling or connecting elements 2 can no longer be accidentally removed, since their flat bottom surface 6 is abutted against the wall (or the DIN guide).

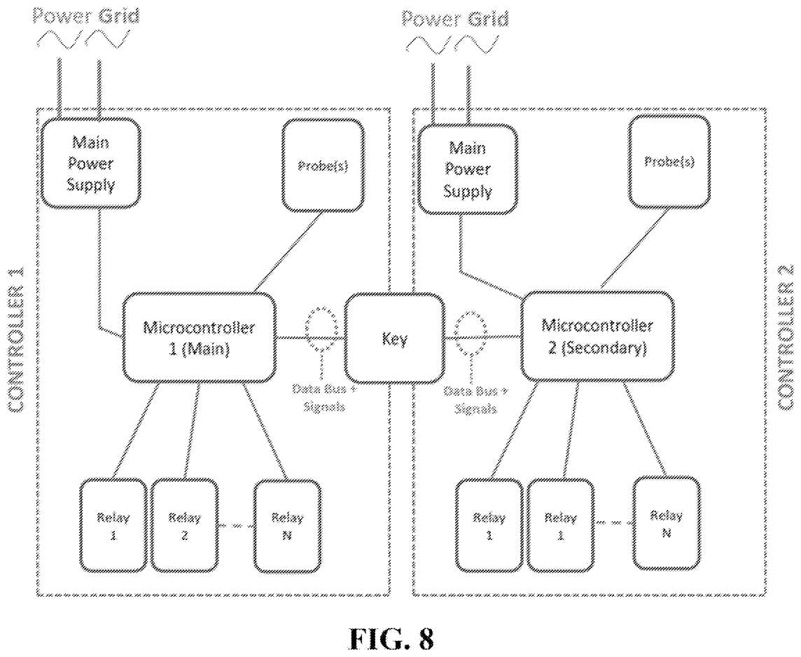

Thanks to the kit according to the present invention, it is possible to connect two or more electric appliances to each other in various ways, as shown by way of example in FIGS. 8 to 12. For example (FIG. 8), two appliances can be connected side by side by a single coupling or connecting element 2 according to this invention so that each appliance is supplied autonomously by the mains and the two appliances can exchange information through the bus of lines of the coupling or connecting element. FIG. 8 shows schematically the circuitry inside the casing of the electric appliances CONTROLLER1, CONTROLLER2. In FIG. 8, CONTROLLER1 corresponds to the first appliance as described above and CONTROLLER2 corresponds to the second appliance as described above. In FIG. 8 the coupling or connecting element 2 is called KEY. In the non-limiting example illustrated in FIG. 8, the electric appliances, that is, the first and second appliances, comprise:
a support, which for example can also be a printed board (PCB), on which electrical lines and electrical pads are defined, in which each electrical line is connected to a respective electrical pad and in which the internal electrical lines comprise data lines intended to convey digital data signals, and optionally also electricity supply lines;
a microcontroller installed on the support and having connectors connected to the data lines.

The appliances may optionally comprise:
one or more RELAY switches installed on the support and connected to the microcontroller so as to be controlled by the microcontroller,
one or more PROBE sensors installed on the support and connected to the microcontroller so as to provide the microcontroller with signals relating to measured quantities.

Thanks to the coupling or connecting element 2, the two appliances schematically shown in FIG. 8 are mechanically and electrically connected to each other in order to allow the two microcontrollers to exchange information. As a result, it becomes possible to form an electrical panel composed of appliances that measure different quantities in which each electric appliance CONTROLLER can take advantage of the measurements made by another appliance of the electrical panel in order to more effectively control its own switches. In addition, the microcontrollers may be programmed so that one of them performs a primary function MICROCONTROLLER (MAIN) and the other(s) are subordinate to the first MICROCONTROLLER (SECONDARY). In other words, preferably, the microcontroller of the first appliance 1 may be configured to control the microcontroller of the second appliance 1a. In other words, preferably, the operation of the microcontroller of the second appliance 1a may be subordinate to the operation of the microcontroller of the first appliance 1.

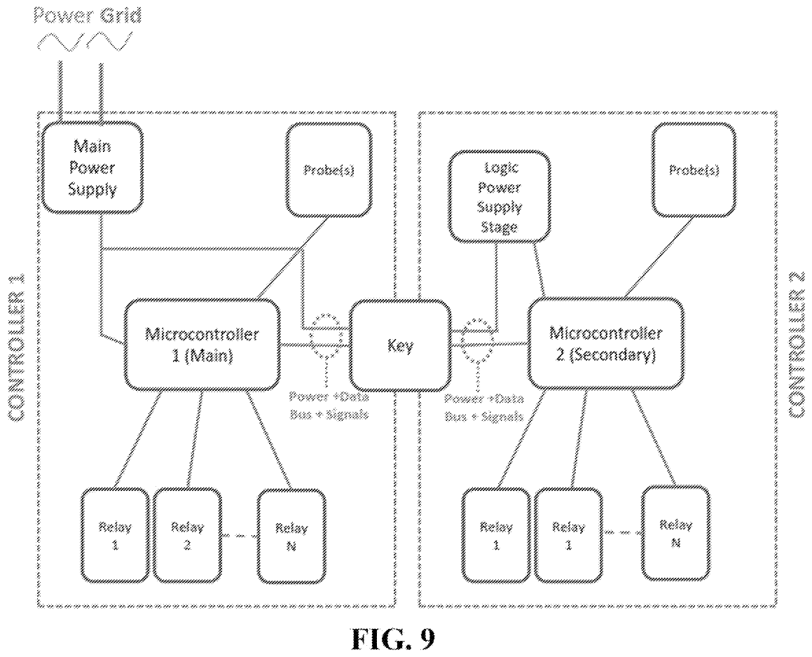

As illustrated in FIG. 9, according to a preferred embodiment of the kit according to the present invention, with the kit according to the present invention it is also possible to connect side by side two appliances by means of a single coupling or connecting element KEY so that only a first appliance CONTROLLER1 is autonomously supplied by the mains POWER SUPPLY and the other appliance CONTROLLER2 can be supplied and exchange information through the bus of lines of the coupling or connecting element KEY. In this case, conveniently the appliance CONTROLLER2 will contain a supply management block LOGIC POWER SUPPLY STAGE that will receive a supply voltage through the coupling or connection element KEY and will have to manage the supply of the internal circuits of the appliance CONTROLLER2. Optionally, the microcontroller MICROCONTROLLER 1 of the first appliance CONTROLLER1 will perform primary functions (MAIN) as it is supplied directly by the mains POWER SUPPLY, while the other microcontroller MICROCONTROLLER2 will perform support functions (SECONDARY) to the first microcontroller MICROCONTROLLER1.

In FIG. 9, CONTROLLER1 corresponds to the first appliance 1 as described above and CONTROLLER2 corresponds to the second appliance 1a as described above. In FIG. 9 the coupling or connecting element 2 is identified as KEY.

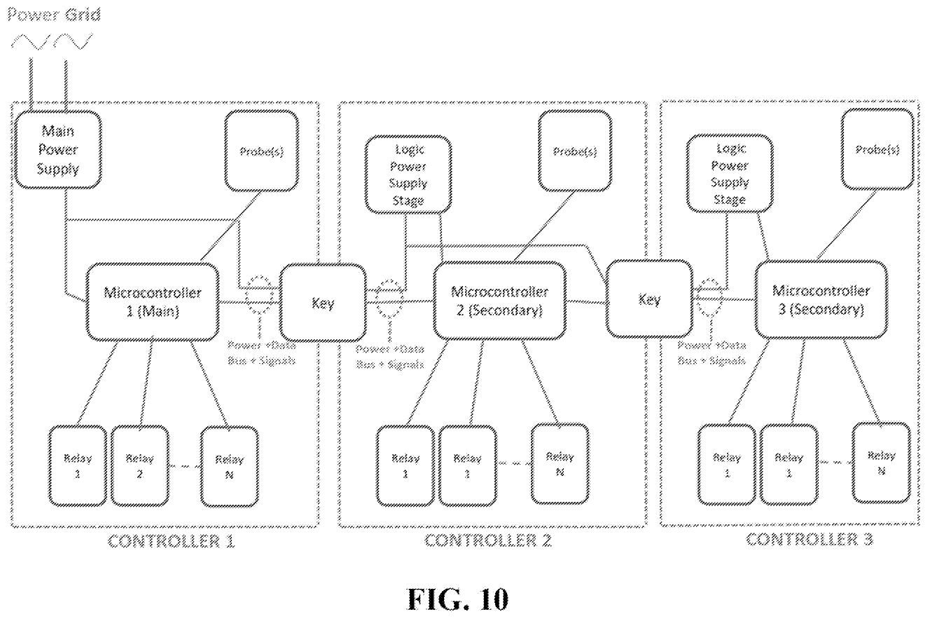

Thanks to the kit according to the present invention, it is possible to connect three (or more) appliances side by side, as illustrated in FIG. 10, by means of two (or more) coupling or connection elements, so as to compose an electrical panel in which a first appliance CONTROLLER1 is autonomously supplied by the mains POWER GRID, while the other appliances CONTROLLER2, CONTROLLER3 are supplied by the first appliance CONTROLLER 1 and can exchange information through the bus of lines of the two coupling or connection elements KEY. Also in this case, as illustrated with reference to FIG. 9, conveniently the appliance CONTROLLER1 will perform primary functions (MAIN) as it is supplied directly by the mains POWER SUPPLY, while the other microcontrollers MICROCONTROLLER2 and MICROCONTROLLER3 will perform support functions (SECONDARY) to the first microcontroller MICROCONTROLLER1. Also in this case, conveniently the appliances CONTROLLER2 and CONTROLLER3 that perform support functions (SECONDARY) will contain a supply management block LOGIC POWER SUPPLY STAGE that will receive a supply voltage through the coupling or connecting element KEY and will have to manage the electricity supply of the internal circuits of the respective electric appliance. Thanks to the coupling or connecting element KEY, the three appliances CONTROLLER1, CONTROLLER2 and CONTROLLER3 will together form an electrical panel that will have the appearance of a single block, because the coupling or connecting elements KEY will mechanically (as well as electrically) constrain the three devices side by side.

In FIG. 10, CONTROLLER1 corresponds to the first appliance 1 as described above and CONTROLLER2 corresponds to the second appliance 1a as described above. The controller 3 corresponds to a third electric appliance 1b. In FIG. 10 the coupling or connecting element 2 is identified as KEY.

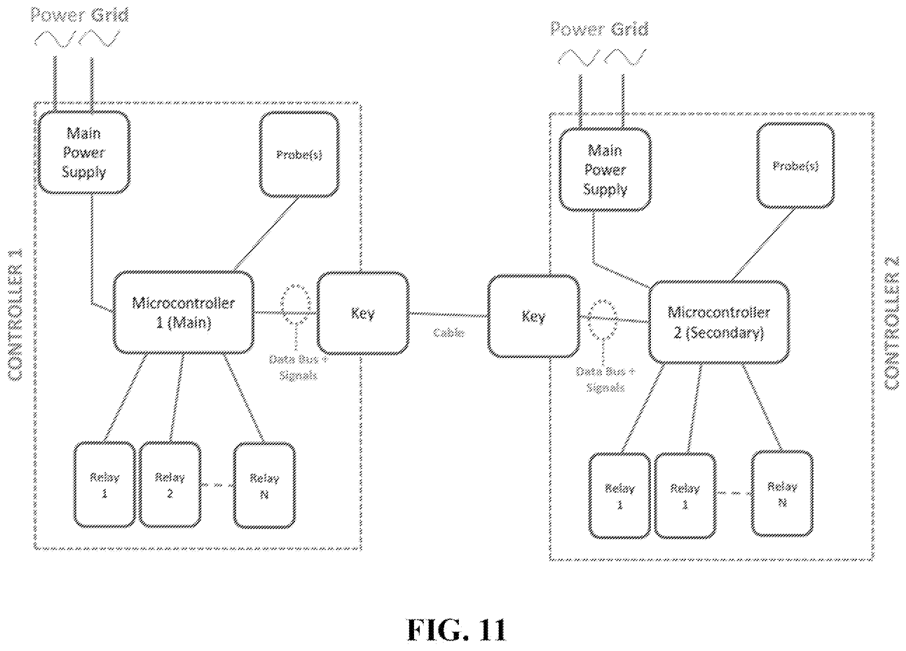

Other connection configurations between electric appliances are also possible with the kit according to the present invention. For example, as illustrated in FIG. 11, if it is not possible to install two appliances CONTROLLER1 and CONTROLLER2 side by side, connecting them through a single coupling or connecting element, two coupling or connecting elements KEY of the kit according to the present invention can still be used and an electrical CABLE can be connected between the free connectors of the two coupling or connecting elements KEY. In FIG. 11, CONTROLLER1 corresponds to the first appliance 1 as described above and CONTROLLER2 corresponds to the second appliance 1a as described above. In FIG. 11 each coupling or connecting element 2 is identified as KEY.

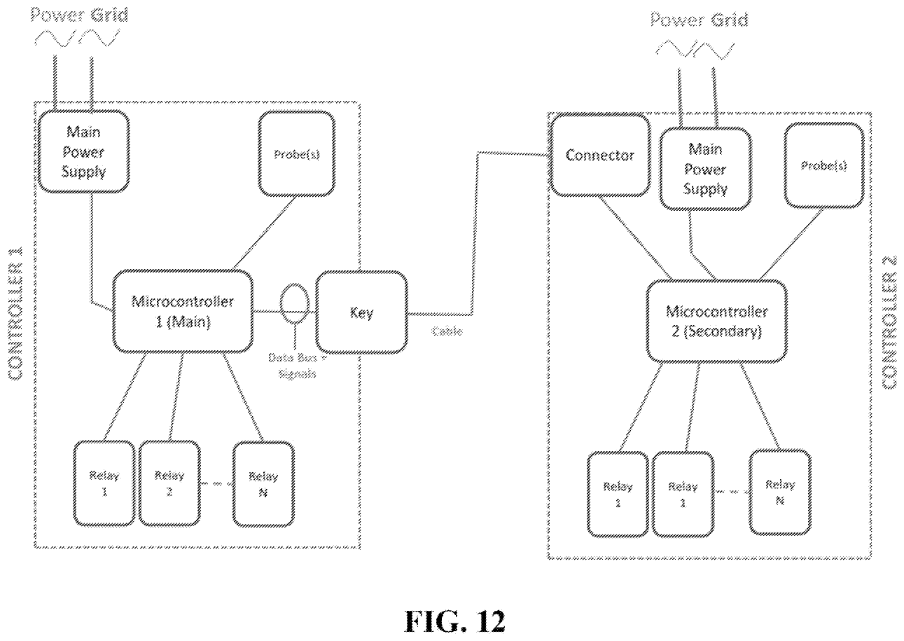

As illustrated in FIG. 12, two appliances CONTROLLER1 and CONTROLLER2 can also be connected remotely with a kit comprising a single coupling or connecting element KEY. In FIG. 12, CONTROLLER1 corresponds to the first appliance 1 as described above. In FIG. 12 the coupling or connecting element 2 is identified as KEY. In this case, the free connectors of the coupling or connecting element KEY must be connected by means of an electrical CABLE to the connectors of the remote appliance CONTROLLER2. Preferably, therefore, the kit can then be provided with an electrical cable configured to be connected to the second electrical connectors 10 of the coupling or connecting element 2. Such a solution can be adopted for example when the remote control appliance 2 is of known type, so it does not have the electrical connection pads that characterise the appliances of the kit according to the present invention. In other words, in FIG. 12, CONTROLLER2 identifies an electric appliance of known type that differs from the second appliance 1a as described above as it does not comprise second electrical pads. It is therefore understood that the kit according to the present invention is fully compatible with the known electric appliances, even if the latter do not have the electrical connection pads left uncovered by the external casing of the appliance, so as to be able to come into contact with the exposed connectors of a coupling or connecting element.

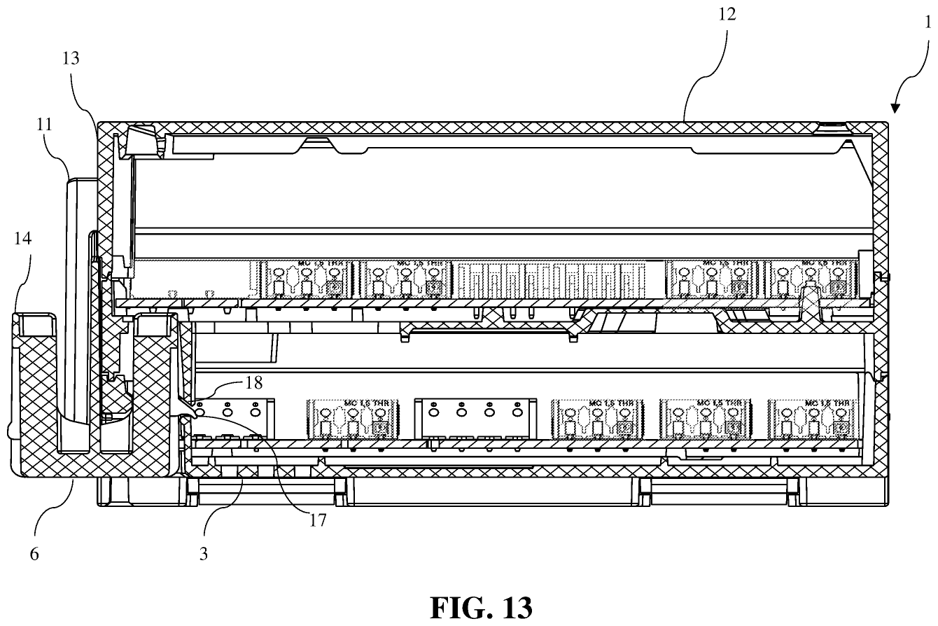

With reference to FIG. 13, according to an embodiment of the kit, the rigid body 14 is provided with irreversible coupling means 17 and the external casing 12 of the first appliance 1 is provided with an irreversible coupling seat 18. Preferably, the irreversible coupling means 17 are made at the first side of the rigid body 14. The rigid body 14 defines, that is to say, on the first side also the irreversible coupling means 17. Preferably, the irreversible coupling seat 18 is made at the first side surface 13 of the external casing 12 of the first appliance 1. The irreversible coupling means 17 and the irreversible coupling seat 18 are configured to achieve a reciprocal irreversible coupling. Preferably, the irreversible coupling means 17 are configured to snap-engage in the irreversible coupling seat 18 so as to achieve a reciprocal irreversible coupling. Basically, the second protrusions and/or grooves 7 and the first grooves and/or protrusions 5 are configured, thanks to the irreversible coupling means 17, to snap into each other in an irreversible manner, so that the first appliance 1 and the coupling or connecting element 2 are configured to be coupled to each other in an irreversible manner.

Alternatively to the embodiment just described, the rigid body 14 is provided with irreversible coupling means 17 at the second side and the external casing of the second appliance 1a is provided with an irreversible coupling seat 18. In other words, the irreversible coupling means 17 are—alternatively—made at the second side of the rigid body 14. The rigid body defines, that is, on the second side on the second side the irreversible coupling means 17. In this case, therefore, the irreversible coupling seat 18 is made at the second side surface of the external casing of the second appliance 1a. The irreversible coupling means 17 and the irreversible coupling seat 18 are configured to achieve a reciprocal irreversible coupling. Preferably, the irreversible coupling means 17 are configured to snap-engage in the irreversible coupling seat 18 so as to achieve a reciprocal irreversible coupling. Basically, the fourth grooves and/or protrusions 16 and the third protrusions and/or grooves 11 are configured to snap-connect, through the irreversible coupling means 17 and the irreversible coupling seat 18, irreversibly into each other, so that the coupling or connecting element 2 can be engaged in the second appliance 1b in an irreversible manner.

Alternatively, the rigid body 14 is provided with irreversible coupling means 17 at the first side and the second side and the external casing of the first appliance 1 is provided with a first irreversible coupling seat 18 and the external casing of the second appliance 1a is provided with a second irreversible coupling seat. In other words, the irreversible coupling means 17 are made at the first side and the second side of the rigid body 14.

According to this alternative embodiment, the irreversible coupling means 17 provided on the first side of the rigid body 14 are configured to snap-engage in the first irreversible coupling seat 18 and the irreversible coupling means 17 provided on the second side of the rigid body 14 are configured to snap-engage in the second irreversible coupling seat so as to achieve an irreversible coupling between them.

If the rigid body 12 is provided with irreversible coupling means 17 and the first appliance 1 and/or the second appliance 1b is provided with a respective irreversible coupling seat, the irreversible coupling means 17 more preferably comprise at least one protruding element, such as a tooth. Even more preferably, the at least one protruding element is configured to adopt a deformed or retracted configuration, during insertion of the coupling or connecting element 2 in the insertion direction, and to adopt a non-deformed or extracted configuration. In the non-deformed or extracted configuration, the protruding element engages the respective irreversible coupling seat 18 opposing its extraction or removal with respect to the irreversible coupling seat 18, particularly in a direction of dis-insertion opposite to the direction of insertion of the rigid body 14.

1. A kit including:
at least one first appliance, which includes:
a support on which first electrical lines and first electrical pads are defined, each electrical line of said first electrical lines being connected to a respective electrical pad of said first electrical pads, wherein said first electrical lines include data lines intended to convey signals of digital data,
a microcontroller installed on said support and having connectors connected to said data lines,
an external casing which encloses said support leaving said first electrical pads exposed, said external casing defining first grooves or protrusions;
at least one coupling element of said first appliance to a second appliance, wherein said coupling element;
has a rigid body defining, on a first side, second protrusions or grooves complementary to said first grooves or protrusions, and
has a bus of electrical lines terminating, at a first end, with first electrical connectors exposed from the first side and, at a second end opposite to said first end, second electrical connectors exposed from a second side opposite to said first side such that, when the coupling element is mounted with the second protrusions or grooves that engage the first grooves or protrusions of the first appliance, the first exposed electrical connectors of the electrical line bus come into contact with said first electrical pads establishing an electrical continuity between the electrical lines of the bus and said first electrical lines of the first appliance.

2. The kit according to claim 1, wherein said rigid body is shaped so as to have a centerline plane, wherein said first side and said second side are opposite with respect to said centerline plane, wherein said electrical line bus is anchored to said rigid body with said first exposed electrical connectors facing from said first side and with said second exposed electrical connectors facing from said second side.

3. The kit according to claim 2, wherein said electrical line bus is embedded in said rigid body.

4. The kit according to claim 2, wherein said electrical line bus is anchored to said rigid body in a removable manner.

5. The kit according to claim 1, wherein said first electrical lines comprise supply lines of said first appliance connected to connectors of an electrical plug.

6. The kit according to claim 1, in which the external casing of said first appliance defines a first flat resting surface for resting against a wall or DIN guide that leaves said first electrical pads exposed and defines said first grooves or protrusions developed on a first side surface of the first appliance, in which the rigid body defines a flat bottom surface such that, when the rigid body of the coupling element engages said first grooves or protrusions and said first exposed electrical connectors come into contact with said first electrical pads, said flat bottom surface of the rigid body is coplanar with said first flat resting surface of said first appliance.

7. The kit according to claim 1, wherein said first appliance comprises:
at least one switch installed on said support and connected to said microcontroller so as to be driven by the microcontroller,
at least one sensor installed on said support and connected to said microcontroller so as to provide the microcontroller with signals relating to measured quantities.

8. The kit according to claim 1, wherein said rigid body, on said second side, has third protrusions or grooves, arranged symmetrically or asymmetrically with respect to said second protrusions or grooves.

9. The kit according to claim 8, comprising a second appliance which includes:
a second support on which second electrical lines and second electrical pads are defined, each electrical line of said second electrical lines being connected to a respective electrical pad of said second electrical pads, wherein said second electrical lines include second data lines intended for conveying digital data signals,
a second microcontroller installed on said second support and having second connectors connected to said second data lines,
at least a second switch installed on said second support and connected to said second microcontroller so as to be driven by the second microcontroller,
at least a second sensor installed on said second support and connected to said second microcontroller so as to provide the second microcontroller with signals relating to measured quantities,
a second external casing which encloses said second support leaving said second electrical pads exposed, said second external casing defining fourth grooves or protrusions complementary to said third protrusions or grooves.

10. The kit according to claim 8, wherein the external casing of said second appliance defines a second flat resting surface for resting against the wall or DIN guide that leaves said second electrical pads exposed and defines said fourth grooves or protrusions formed on a second side surface of the second appliance so that when the rigid body of the coupling element engages said first grooves or protrusions and said fourth grooves or protrusions, and when said first and second exposed electrical connectors come into contact respectively with said first and second electrical pads, said flat bottom surface of the rigid body is coplanar with said first flat resting surface and said second flat resting surface.

11. The kit according to claim 9, wherein said second electrical lines comprise supply lines of said second appliance connected to supply pads of said second electrical pads.

12. The kit according to claim 1, wherein the external casing of said first appliance defines a first flat surface for resting against a wall or DIN guide, wherein, in use, the first flat resting surface faces a rear side of the first appliance opposite to a use side of the first appliance, and wherein the first grooves or protrusions and the second protrusions or grooves are configured to be inserted into each other in an insertion direction, wherein said insertion direction goes from said rear side to said side of use.

13. The kit according to claim 1, wherein said second protrusions or grooves and said first grooves or protrusions are configured to slide reversibly inside each other so that said first appliance and said coupling element are configured to be mutually coupled/uncoupled in a reversible manner.

14. The kit according to claim 1, wherein said second protrusions or grooves and said first grooves or protrusions are configured to snap into each other in an irreversible manner so that said first appliance and said coupling element are configured to be coupled to each other in an irreversible manner.

15. The kit according to claim 9, wherein said rigid body is provided with irreversible coupling means at the second side and the external casing of the second appliance is provided with an irreversible coupling seat and wherein the irreversible coupling means are configured to achieve a reciprocal coupling in an irreversible manner.
